(19) United States
(12) Patent Application Publication
(10) Pub. No.: US 2005/0216821 A1
(43) Pub. Date: Sep. 29, 2005

(54) Mapping method for encoded bits using LDPC code, transmitting and receiving apparatuses employing this method, and program for executing this method

(76) Inventor: Kohsuke Harada, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/076,050

(22) Filed: Mar. 10, 2005

(30) Foreign Application Priority Data
Mar. 24, 2004 (JP) 2004-088088

(51) Int. Cl. H04L 5/12; H04L 23/02; H03M 13/00; G06F 11/00

(52) U.S. Cl. 714/801

(57) ABSTRACT

A method for mapping of coded bits using a low density parity check (LDPC) code, comprises encoding information bits by using the LDPC code to generate coded bits, sorting the coded bits in accordance with degrees of variable nodes represented by a parity check matrix of the LDPC code, dividing the sorted coded bits into a plurality of groups in accordance with a using modulation scheme, and mapping the coded bits to respective modulation signal points by considering an error resistance of each of the groups and an error resistance of a corresponding one of the modulation signal points.

### CROSS-REFERENCE TO RELATED APPLICATIONS

This application is based upon and claims the benefit of priority from prior Japanese Patent Application No. 2004-088088, filed Mar. 24, 2004, the entire contents of which are incorporated herein by reference.

### BACKGROUND OF THE INVENTION

1. Field of the Invention

The present invention relates to the field of digital radio communications, and more particularly to a method for mapping encoded bits using a low density parity check (LDPC) code, which is characterized by digital data error correction and its modulation scheme, also to a transmitting apparatus and receiving apparatus employing this method and program for executing this method.

2. Description of the Related Art

When using a certain modulation scheme, coded bit sequences assigned to respective modulation signal points generally have different resistances to errors at the modulation signal points in a communication channel. Further, in this case, a plurality of transmitted coded bit sequences contain, due to modulation, portions that exhibit high resistance to bit errors in the communication channel, and portions that exhibit low resistance to them. If portions exhibiting high resistance to bit errors continue, this may well degrade the error rate characteristic when decoding encoded digital information.

In conventional radio communication systems, to solve this problem, coded bit sequences are mixed by interleaving to thereby disperse, at the receiver side, continuous bit errors that occur in a communication channel. This suppresses the influence of the continuous bit errors in the communication channel upon decoding. This method is effective when a coding scheme employed at the transmission side provides all bit sequences with uniform resistance to errors.

LDPC codes are error correction codes and are considered a technique substituting for turbo codes. Further, it is known from, for example, Jpn. Pat. Appln. KOKAI Publication No. 2003-115768 that LDPC codes have excellent asymptotic performance. However, each LDPC code itself exhibits different resistances to errors. Therefore, simply by dispersing the non-uniform error resistance at modulation signal points, the characteristics of LDPC codes are not always sufficiently utilized.

As described above, in the conventional radio communication systems, encoding and interleaving of digital data are performed so that the influence of errors at modulation signal points in a communication channel upon coded bit sequences will be uniformly dispersed. However, if an LDPC code exhibiting different resistances to errors is employed for a coded bit sequence, it does not sufficiently exhibit its characteristics. Furthermore, also when an LDPC encoder is constructed, no consideration is given to error resistances in a communication channel, therefore LDPC codes used in the LDPC encoder are not always suitable for the characteristics of the communication channel.

### BRIEF SUMMARY OF THE INVENTION

According to a first aspect of the invention, there is provided a method for mapping of coded bits using a low density parity check (LDPC) code, comprises encoding information bits by using the LDPC code to generate coded bits; sorting the coded bits in accordance with degrees of variable nodes represented by a parity check matrix of the LDPC code; dividing the sorted coded bits into a plurality of groups in accordance with a using modulation scheme; and mapping the coded bits to respective modulation signal points by considering an error resistance of each of the groups and an error resistance of a corresponding one of the modulation signal points.

According to a second aspect of the invention, there is provided a transmitting apparatus for transmitting coded data, comprises an encoder which encodes information bits using a low density parity check (LDPC) code, and generates coded bits; a sorting unit configured to sort the coded bits in accordance with degrees of variable nodes represented by a parity check matrix of the LDPC code; a dividing unit configured to divide the sorted coded bits into a plurality of groups in accordance with a using modulation scheme; and a mapping unit configured to map the coded bits to respective modulation signal points by considering an error resistance of each of the groups and an error resistance of a corresponding one of the modulation signal points provides each of the sufficient error resistances; a modulation unit configured to modulate the mapped coded bits using the modulation scheme; and a transmitting unit configured to transmit the modulated mapped coded bits.

According to a third aspect of the invention, there is provided a receiving apparatus comprising a receiving unit configured to receive the modulated mapped coded bits from the transmitting apparatus of the second aspect.

According to a fourth aspect of the invention, there is provided a program stored in a computer readable medium, the program for mapping of coded bits using a low density parity check (LDPC) code, the program comprises means for instructing the computer to encode information bits using the LDPC code and generate coded bits; means for instructing the computer to sort the coded bits in accordance with degrees of variable nodes represented by a parity check matrix of the LDPC code; means for instructing the computer to divide the sorted coded bits into a plurality of groups in accordance with a using modulation scheme; and means for instructing the computer to map the coded bits to respective modulation signal points by considering an error resistance of each of the groups and an error resistance of a corresponding one of the modulation signal points.

According to a fifth aspect of the invention, there is provided a program stored in a computer readable medium, the program for mapping of coded bits using a low density parity check (LDPC) code, the program comprises means for instructing the computer to encode information bits using the LDPC code and generate coded bits; means for instructing the computer to sort the coded bits in accordance with degrees of variable nodes represented by a parity check matrix of the LDPC code; means for instructing the computer to divide the sorted coded bits into a plurality of groups in accordance with a using modulation scheme; means for instructing the computer to detect a communication channel state between a transmitting apparatus and a receiving apparatus; and means for instructing the computer to map the coded bits to respective modulation signal points by considering an error resistance of each of the groups, an error resistance of a corresponding modulation signal point of the modulation signal points and the detected communication channel state.

### BRIEF DESCRIPTION OF THE SEVERAL VIEWS OF THE DRAWING

FIG. 1 is a block diagram illustrating a radio transmitting apparatus and radio receiving apparatus according to a first embodiment of the invention;

FIG. 2 is a bipartite graph illustrating a case where all variable nodes have the same degree;

FIG. 3A illustrates an example of a parity check matrix used when all variable nodes have the same degree;

FIG. 3B illustrates an example of a parity check matrix used when variable nodes have different degrees;

FIG. 4 is a bipartite graph illustrating deletion, addition and switching of paths;

FIG. 5 is a view useful in explaining the operation of FIG. 4 on the parity check matrix;

FIG. 6 is a bipartite graph useful in explaining the decoding processing of LDPC decoder appearing in FIG. 1;

FIG. 7 is a bipartite graph illustrating a case where variable nodes of different degrees are included;

FIG. 8 is a view illustrating modulation signal points and their error resistances acquired when the modulation scheme is 4-ary PAM;

FIG. 9 is a flowchart illustrating the operation of the radio transmitting apparatus of FIG. 1;

FIG. 10 is a view illustrating different ways of labeling performed on modulation signal points in 4-ary PAM;

FIG. 11 is a view illustrating a way of mapping using labeling when the modulation scheme is 8-ary PSK;

FIG. 12 is a block diagram illustrating a radio transmitting apparatus and radio receiving apparatus according to a second embodiment of the invention;

FIG. 13 is a flowchart illustrating the operation of the radio transmitting apparatus of FIG. 12;

FIG. 14 is a view useful in explaining determination of a mapping pattern based on a frequency-base communication channel state;

FIG. 15 is a view useful in explaining determination of a mapping pattern based on a frequency-base communication channel state;

FIG. 16 is a view useful in explaining mapping control for LDPC bit sequences, which follows the state of a communication channel;

FIG. 17 is a view illustrating operation examples of the radio transmitting apparatus and radio receiving apparatus shown in FIG. 12;

FIG. 18 is a block diagram illustrating a radio transmitting apparatus and radio receiving apparatus according to a third embodiment of the invention;

FIG. 19 is a block diagram illustrating a radio transmitting apparatus and radio receiving apparatus according to a modification of the third embodiment of the invention;

FIG. 20 is a block diagram illustrating a radio transmitting apparatus and radio receiving apparatus according to a fourth embodiment of the invention;

FIG. 21 is a bipartite graph useful in explaining sorting, grouping and mapping performed by the radio transmitting apparatus shown in FIG. 20;

FIG. 22 is a block diagram illustrating a radio transmitting apparatus and radio receiving apparatus according to a first modification of the fourth embodiment of the invention;

FIG. 23 is a bipartite graph useful in explaining sorting, grouping and mapping performed by the radio transmitting apparatus shown in FIG. 22;

FIG. 24 is a block diagram illustrating a radio transmitting apparatus and radio receiving apparatus according to a second modification of the fourth embodiment of the invention;

FIG. 25 is a bipartite graph useful in explaining sorting, grouping and mapping performed by the radio transmitting apparatus shown in FIG. 24;

FIG. 26 is a block diagram illustrating a radio transmitting apparatus and radio receiving apparatus according to a fifth embodiment of the invention; and

FIG. 27 is a bipartite graph illustrating a pattern of puncture performed by the radio transmitting apparatus shown in FIG. 26.

### DETAILED DESCRIPTION OF THE INVENTION

Referring to the accompanying drawings, a detailed description will be given of encoded bit mapping methods using LDPC codes, transmitting and receiving apparatuses, and program for executing this method according to embodiments of the invention.

Firstly, a digital radio communication system using low density parity check (LDPC) codes as error correction codes, to which the embodiments are related, will be described. In this system, a radio transmitting apparatus produces coded bit sequences by inputting digital data to an LDPC encoder, and assigns them to respective modulation signal points. On the other hand, the radio receiving apparatus acquires likelihood information on each coded bit sequence from the information received by the modulation signal points, based on the relationship between each coded bit sequence assigned to the modulation signal points by the radio transmitting apparatus, and the corresponding error correction code. After that, the radio receiving apparatus decodes each received coded bit sequence using the likelihood information, to thereby acquire desired digital data.

In the radio communication system, the above-mentioned modulation signal points are set using, for example, M-ary phase shift keying (PSK), M-ary quadrature amplitude modulation (QAM), M-ary pulse amplitude modulation (PAM), M-ary amplitude modulation/phase modulation (AMPM), M-ary pulse position modulation (PPM), orthogonal frequency division multiplexing (OFDM), code division multiple access (CDMA) or ultra wide band modulation (UWB).

### First Embodiment

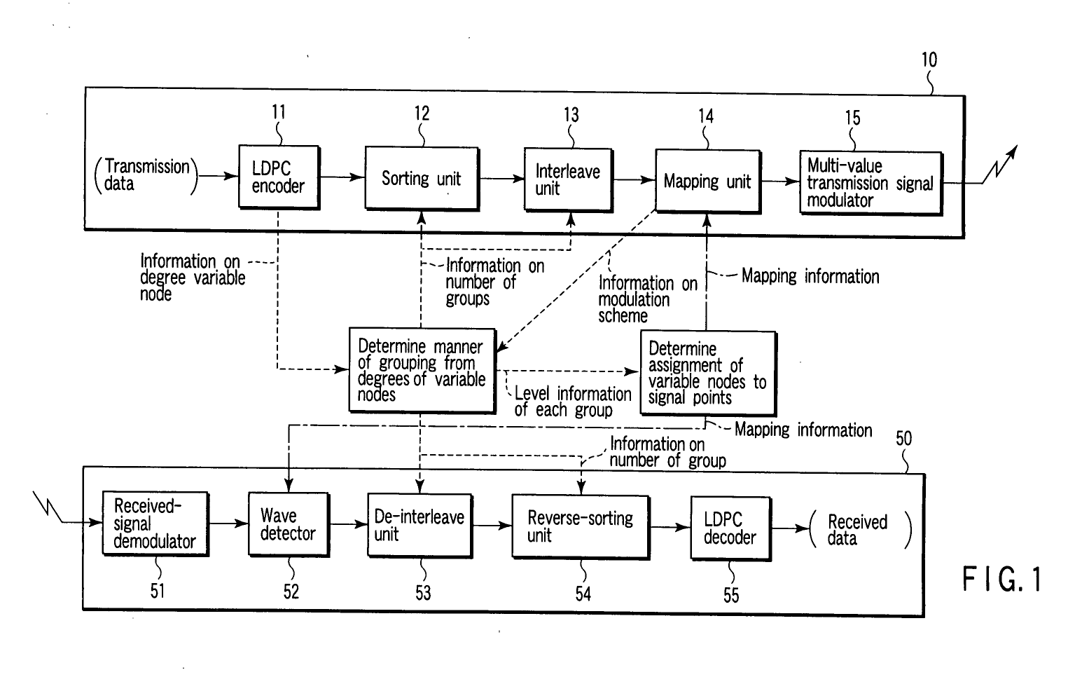

Referring to FIG. 1, a radio transmitting apparatus and radio receiving apparatus according to the first embodiment will be described. FIG. 1 is a block diagram of these radio transmitting apparatus and radio receiving apparatus.

The radio transmitting apparatus denoted by reference numeral 10 can appropriately map, to modulation signal points, respective bit sequences encoded by an LDPC encoder to optimize their error resistances. As seen from FIG. 1, the radio transmitting apparatus 10 comprises an LDPC encoder 11, sorting unit 12, interleave unit 13, mapping unit 14 and multi-ary transmission signal modulator 15.

The LDPC encoder 11 receives transmission data, and performs LDPC coding on it based on a generator matrix G. The generator matrix G is defined as a matrix that satisfies H×G=0 in a predetermined parity check matrix H. LDPC coding is performed to acquire C that satisfies V×G=C where V represents a digital data sequence constituting the transmission data. This “C” is an LDPC-coded bit sequence and is called a coded bit sequence.

The sorting unit 12 sorts the acquired coded bit sequence in accordance with the degrees of variable nodes obtained from the parity check matrix H. The degree of each variable node acquired from the parity check matrix H corresponds to the number of components “1” contained in each column vector in the parity check matrix H. Specifically, the parity check matrices H shown in FIG. 3A and FIG. 3B will be described. In these figures, each column of the parity check matrix H corresponds to a variable node, i.e., the first to sixth columns correspond to variable nodes n1, n2, . . . , n6. In the parity check matrix shown in FIG. 3A, all variable nodes n1, n2, . . . , n6 have a degree of 2. In contrast, in the parity check matrix shown in FIG. 3B, the degrees of variable nodes n1, n2, n3, n4, n5 and n6 are 3, 3, 3, 1, 1 and 1, respectively. When not all variable nodes have the same degree as in the case of FIG. 3B, the sorting unit 12 sorts the acquired coded bit sequence.

Further, each bit encoded using the generator matrix G that is obtained from the parity check matrix H corresponds to a variable node. Accordingly, the degree of each variable node in the parity check matrix H can be considered to correspond to each bit of each coded bit sequence. The sorting unit 12 considers that the degree of each variable node is that of the corresponding encoded bit, thereby sorting the coded bit sequence. Sorting is performed in the order of either ascending powers or descending powers. In the example of FIG. 3B, when sorting is performed in the order of ascending powers, the variable nodes are sorted in the order of n6, n5, n4, n3, n2 and n1.

The sorting unit 12 also divides each sorted coded bit sequence into a predetermined number of groups corresponding to a modulation scheme employed in the radio transmitting apparatus 10. The number of groups corresponding to the modulation scheme is, for example, the level number of the error resistance that differs between modulation signal points. For instance, in the case of 4-ary PAM, each sorted coded bit sequence is divided into two groups, while in the case of 8-ary PSK, it is divided into three groups.

The interleave unit 13 performs interleaving in units of coded bit sequence groups made by the sorting unit 12. The interleave unit 13 is a dispensable unit, but may be omitted. In other words, coded bit sequences processed by the sorting unit 12 may be directly output to the mapping unit 14.

The mapping unit 14 assigns a group of coded bit sequences to each modulation signal point. Specifically, in accordance with error resistance levels corresponding to a modulation scheme used at the transmission side, groups of coded bit sequences are assigned to respective modulation signal points. For instance, as shown in FIG. 11, labeling is made using labels X, Y and Z. In the above-mentioned case where there are three groups of n6 and n5, n4 and n3, and n2 and n1, they are assigned to X, Y and Z, respectively. How to assign the groups to the labels is determined from the modulation scheme and/or communication channel. For example, a certain assignment result exhibits good characteristics on a Gaussian noise communication channel, but does not always exhibit best characteristics on a communication channel on which, for example, fading occurs. In the case of FIG. 11, label Z exhibits the lowest resistance to errors, while labels X and Y exhibit the same resistance that is higher than that of label Z. The magnitudes of the degrees of the encoded bits in FIG. 11 are decreased in the order of n6 and n5, n4 and n3, and n2 and n1. Further, the greater the degree of an encoded bit, the higher the possibility of correcting errors. This is because the greater the degree, the more often likelihood information on a communication channel can be used. In the case of FIG. 11, the group of coded bit sequences of the lowest communication error resistance is assigned to a label of the highest communication error resistance. Similarly, the group of coded bit sequences of the second lowest communication error resistance is assigned to a label of the second highest communication error resistance. That is, in that case, a variable node exhibiting a high resistance to an error in a coded bit sequence, i.e., a variable node of a high degree, is assigned to a subcarrier of a bad condition. In contrast, a variable node exhibiting a low resistance to an error in a coded bit sequence, i.e., a variable node of a low degree, is assigned to a subcarrier of a good condition. Thus, the resistance of the entire system to errors is enhanced.

The mapping of bit sequences encoded by the LDPC encoder 11 as described above prevents the LDPC encoder 11 from carelessly assigning a bit sequence of a low error resistance, like a randomly interleaved coded bit sequence, to a modulation signal point of a low error resistance at the transmitting side. This being so, a more reliable communication system using LDPC codes can be established.

The multi-ary transmission signal modulator 15 modulates the signal output from the mapping unit 14, using the modulation scheme referred to when the sorting unit 12 has performed grouping, and the modulation scheme referred to when the mapping unit 14 has performed mapping. The resultant modulated signal is transmitted to a radio receiving apparatus 50.

On the other hand, the radio receiving apparatus 50 comprises a received signal demodulator 51, wave detector 52, de-interleave unit 53, reverse-sorting unit 54 and LDPC decoder 55 as shown in FIG. 1.

The received signal demodulator 51 receives a signal transmitted from the radio transmitting apparatus 10, and demodulates it. The wave detector 52 specifies a coded bit assigned to each modulation signal point, and acquires the likelihood-value of each received bit corresponding to the specified coded bit. The likelihood-value of a certain received bit is a probability indicating whether this bit is 0 (or whether this bit is 1).

The de-interleave unit 53 performs de-interleaving on the likelihood-values of the bits of the received bit sequence. The de-interleave unit 53 corresponds to the interleave unit 13. Where there is no interleave unit 13, no de-interleave unit 53 is employed. In this case, the output of the wave detector 52 is directly input to the reverse-sorting unit 54.

The reverse-sorting unit 54 performs reverse sorting on the de-interleaved bit sequence using the degree of a variable node corresponding to the de-interleaved bit sequence. As a result, the order of the bits of the coded bit sequence sorted by the sorting unit 12 is returned to the original order.

The LDPC decoder 55 assigns, to a variable node, the likelihood-value of a coded bit received from each modulation signal point, thereby estimating a coded bit sequence C′, C′×H=0, from the finally converged likelihood-value, and outputting the estimated coded bit sequence C′.

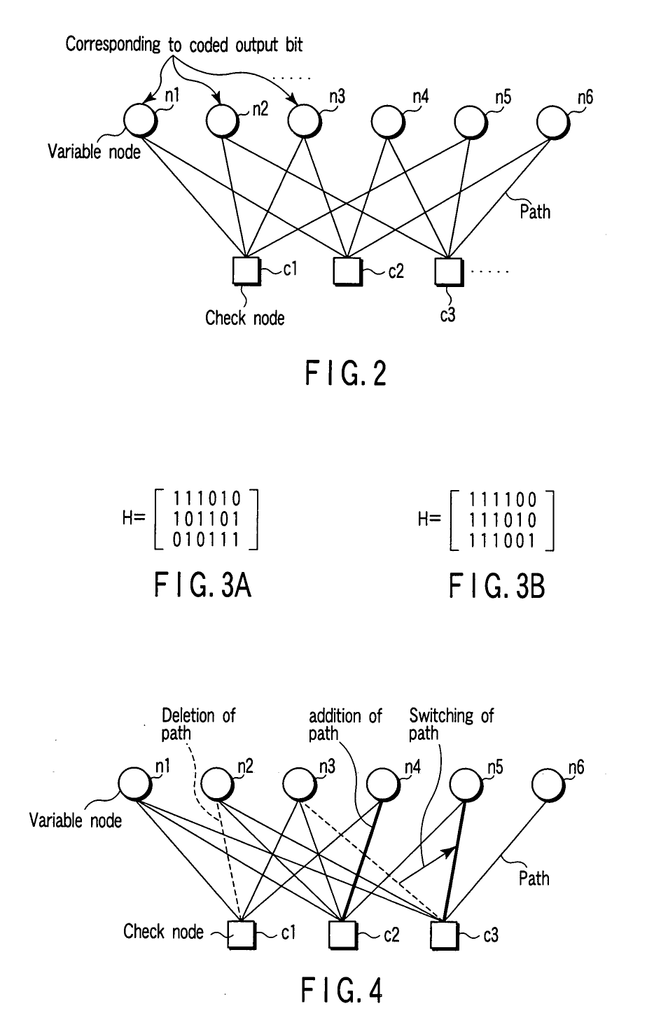

Referring then to FIG. 2 and FIG. 3A, LDPC encoding will be described.

LDPC encoding is an encoding method based on, for example, the bipartite graph as shown in FIG. 2. In the LDPC encoding method, a parity check matrix H corresponding to the bipartite graph of FIG. 2 is prepared, and a generator matrix G that satisfies H×G=0 is acquired. Further, a coded bit sequence C that satisfies V×G=C is acquired, V representing a transmission digital data sequence. The coded bit sequence C is assigned and transmitted to a modulation signal point. At this time, the coded bit sequence satisfies C×H=0. At the receiving side, decoding is performed by selecting a bit sequence that satisfies C′×H=0, C′ representing the likelihood of a coded bit sequence received from the modulation signal point and containing an error. Thus, a desired data sequence is acquired.

A bipartite graph similar to that of FIG. 2 can be made to correspond to a parity check matrix. In other words, if a bipartite graph is given, a parity check matrix is determined, or vise versa. For example, the parity check matrix as shown in FIG. 3A is acquired from the bipartite graph of FIG. 2. Further, in the bipartite graph of FIG. 2, the column vectors of the parity check matrix H shown in FIG. 3A correspond to the respective variable nodes shown in FIG. 2, and the row vectors in the former correspond to the respective check node in the latter. Furthermore, the positions of components “1” included in the parity check matrix H correspond to the respective paths that connect the variable nodes to the check nodes. For instance, if the position of a certain component “1” is between the second row and third column of the matrix, this means that the second check node is connected to the third variable node in the bipartite graph.

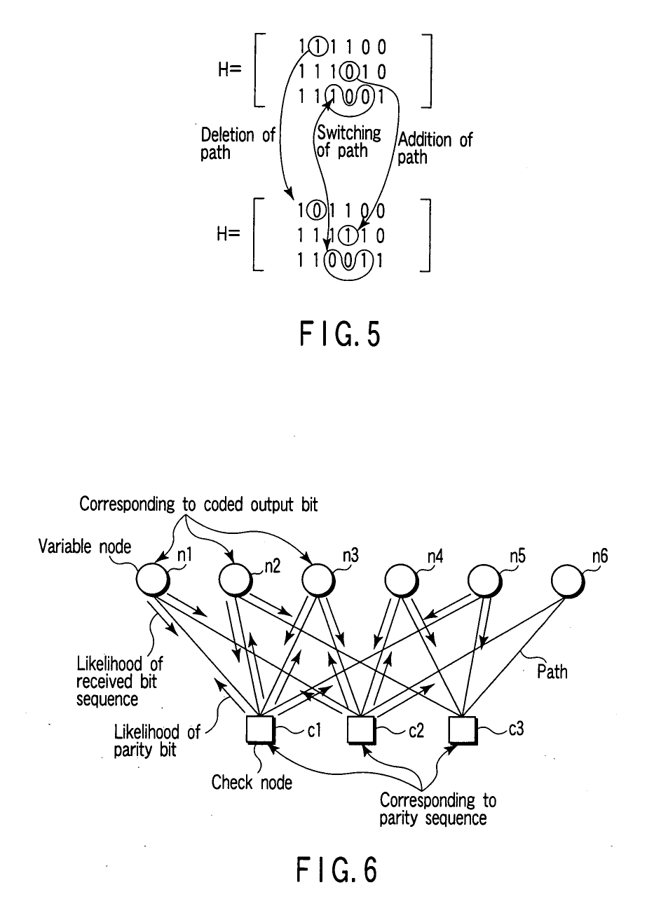

Instead of sorting performed using the degrees of variable nodes before grouping executed in accordance with a communication-channel state, the same effect can be acquired using a bipartite graph symbolically indicating the encoding operation of the LDPC encoder 11. This method will be described below with reference to FIGS. 4 and 5.

The same effect as that of sorting can be acquired by changing the paths in the bipartite graph. In this case, since the distribution of degrees can be changed by changing the positions of the components “1” of the parity check matrix H, labeling of resistances by sorting can be omitted. Further, in this case, in accordance with the changes in the parity check matrix H, it is necessary to change the components of the generator matrix G. The error resistance can be changed by changing the number of the components “1” of the parity check matrix in accordance with a communication channel state.

Specifically, a description will be given of the case of FIG. 4 illustrating another partite graph. FIG. 4 shows deletion, addition and switching of paths. Further, FIG. 5 shows changes in the parity check matrix corresponding to the deletion, addition and switching of paths in the partite graph of FIG. 4. That is, when adding a path, the corresponding matrix element is changed from “0” to “1”. When switching paths, the corresponding two matrix elements “0” and “1” are replaced. Further, when deleting a path, the corresponding matrix element is changed from “1” to “0”. From this, it can be understood that sorting using the degrees of variable nodes is equivalent to replacement of column vectors.

Referring then to FIG. 6, a description will be given of decoding by the LDPC decoder 55. FIG. 6 is a bipartite graph useful in explaining decoding by the LDPC decoder 55.

Decoding of an LDPC-encoded bit sequence is performed by repeating the transfer of likelihood information on received data along the paths between variable nodes and check nodes in the bipartite graph. In this case, the likelihood of each coded bit received from a modulation signal point is assigned to the corresponding variable node, whereby a bit sequence C′, C′×H=0, is estimated from the finally converged likelihood-value and output, which is the termination of decoding.

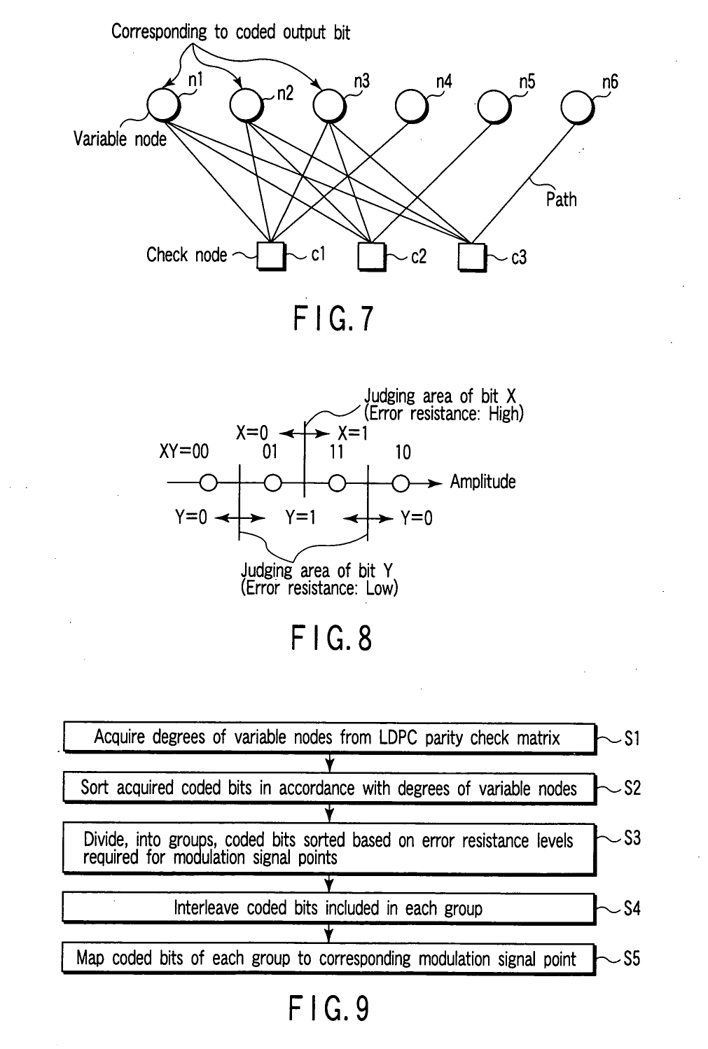

Referring to FIG. 7, a description will be given of the case where different bit error resistances result from decoding between variable nodes.

In the bipartite graph of FIG. 2 differing from that of FIG. 7, each variable node has two paths, and each check node has four paths. In this case, the likelihood information on all variable nodes is acquired from two check nodes, while all check nodes use likelihood information from four variable nodes. Since the same amount of information is transferred between each pair of nodes, the same resistance to errors can be acquired between coded bit sequences.

In contrast, in the bipartite graph of FIG. 7 (corresponding to the parity check matrix shown in FIG. 3B), different amounts of likelihood information are transferred from the check nodes to the variable nodes. For example, in the bipartite graph of FIG. 7, the left-hand three variable nodes each have three paths, while the right-hand three variable nodes each have only one path. Accordingly, concerning the right-hand three variable nodes, their likelihood-values, i.e., their coded bits, are estimated from a smaller amount of likelihood information than in the case of the left-hand three variable nodes. This means that the variable nodes have different resistances to errors.

Assume that a radio communication system utilizes a modulation scheme with a plurality of modulation signal points, or bits assigned in a time-base domain and frequency-base domain on a fading communication channel have different resistances to errors. In these cases, a method such as the interleave method for dispersing error patterns of coded bits, which is only focused on modulation signal pointes and fading error patterns, does not consider resistance patterns to errors in LDPC-encoded bit sequences. Therefore, even if processing such as interleaving is performed, an appropriate dispersion of error resistances is not always realized. Further, even if error patterns are dispersed on a communication channel, this does not always enhance the resistances of LDPC codes to errors.

In light of the above, the radio transmitting apparatus and radio receiving apparatus of the first embodiment provide an optimal model of mapping coded bit sequences to modulation signal points, and an interleave design model based on this mapping, which are for use in a radio communication system utilizing LDPC codes. These models are useful even when LDPC-encoded bit sequences include those having different resistances to errors.

Referring to FIG. 8, a description will be given of a specific example using four-ary PAM modulation scheme, in which coded bit sequences are made to correspond to respective modulation signal points.

In the case of using the four-ary PAM modulation scheme as shown in FIG. 8, coded bits XY assigned to respective modulation signal points have different error resistances. Bit X only determines whether X=0 (or whether X=1) depending upon whether the amplitude is lower than a certain-ary, whereas bit Y must determine whether Y=0 (or whether Y=1) if the amplitude falls within a certain range, and if the amplitude falls outside the range. The determination as to whether the amplitude falls within a certain range is more difficult than the determination as to whether the amplitude is higher than a certain-ary. In the former determination, the possibility of acquiring an erroneous result is high. From this, it can be understood that in the case of FIG. 8, bit X has a higher error resistance than bit Y.

If the bit of a coded bit sequence encoded by the LDPC encoder 11, the variable node corresponding to which has a smaller number of paths, i.e., the bit having a low error resistance, is assigned as bit Y in FIG. 8, it is very possible that the corresponding modulation signal point also has a low error resistance, and hence the characteristics of the entire system are degraded. However, if coded bit sequences are assigned to modulation signal points so that the error resistances of the coded bit sequences and those of the modulation signal points do not weaken each other, the whole communication system using the LDPC codes can have a high resistance to errors.

Referring now to FIG. 9, the operation of the radio transmitting apparatus 10 shown in FIG. 1 will be described.

In accordance with, for example, the flow shown in FIG. 9, the LDPC encoder of radio transmitting apparatus 10, which incorporates variable nodes differing in the number of paths connected (i.e., differing in degree), encodes each bit sequence, using the parity check matrix H of a corresponding LDPC code, thereby mapping each coded bit sequence to a corresponding modulation signal point.

Firstly, the degrees of all variable nodes are acquired from the parity check matrix H (step S1). The degree of each variable node may be acquired from a bipartite graph constituting the parity check matrix H, or from the number of the components “1” included in each column vector, since the number of paths of each variable node corresponds to the number of the components “1” included in each column vector of the parity check matrix H. The bits of a bit sequence encoded by a generator matrix G acquired from the parity check matrix H directly correspond to the variable nodes. Accordingly, the degree of each variable node in the parity check matrix H is considered the degree of each bit of the coded bit sequence.

Subsequently, the sorting unit 12 sorts the acquired coded bit sequence in accordance with the degrees of the variable nodes acquired from the parity check matrix H (step S2). The order of sorting may be the order of either ascending powers or descending powers. Further, the column vectors of the parity check matrix H may be or may not be sorted in accordance with the sorting of the coded bit sequence. The universality is also not lost by these.

Using the error resistance level required at the corresponding modulation signal point on the communication channel, the sorting unit 12 further divides, into groups, the coded bit sequence sorted based on the degrees of the variable nodes (step S3). In the case of, for example, four-ary PAM modulation shown in FIG. 6, two bits XY assigned to each modulation signal point have different error resistance levels, i.e., two error resistance levels. In the example of FIG. 8, the sorting unit 12 forms a group with a larger number of degrees, and a group with a smaller number of degrees. Also in the case employing another modulation scheme, the error resistance level is determined by the arrangement of modulation signal points and the mapping of bits to the respective modulation signal points. Furthermore, in grouping using degrees, it does not matter if the nodes in the groups have the same degree or not.

After that, the interleave unit 13 interleaves the coded bits in units of groups made by the sorting unit 12 (step S4). The universality is not lost regardless of whether this processing is performed. Thereafter, the mapping unit 14 maps the grouped coded bits to the respective modulation signal points (step S5). In this case, the coded bits are assigned which are grouped in accordance with the error resistance levels determined by the modulation scheme employed at the transmitting side.

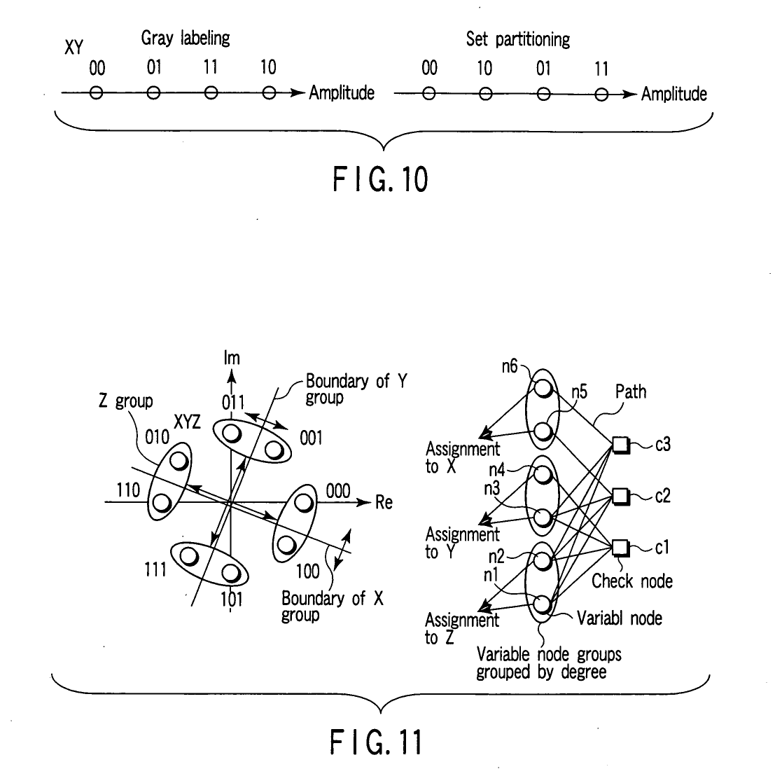

Referring to FIG. 10, a description will be given of an example of a method for mapping coded bits to respective modulation signal points subjected to different labeling processes. Specifically, FIG. 10 shows a four-ary PAM case where the modulation signal points are subjected to different labeling processes.

Gray labeling and set partitioning are typical binary labeling processes performed on modulation signal points in the case of four-ary PAM. In gray labeling and set partitioning of FIG. 10, bit X and bit Y assigned to each signal point have different error probabilities. Gray labeling shown in FIG. 10 is binary labeling similar to that of FIG. 8, in which bit X has a higher error resistance then bit Y. This can easily be understood from the judging area of signal points and labeled bits described above with reference to FIG. 8.

On the other hand, in set partitioning, the error probability of bit X is higher than that of bit Y. However, if bit X is correctly judged and a subset of bit X is determined, the error probability of bit Y is further reduced. Utilizing this feature, the standard of assigning each variable node to gray label and set partition is defined.

If as in the radio receiving apparatus 50 shown in FIG. 1, the wave detector 52 cannot receive the determination result of the LDPC decoder 55, the reliability levels of bit X and bit Y acquired from the communication channel directly influences decoding characteristics. In gray labeling in FIG. 10, a group including a variable node that has a high degree, i.e., has a large number of paths, is assigned to bit Y of high error probability. On the other hand, a group including a variable node that has a low degree, i.e., has a small number of paths, is assigned to bit X of low error probability. As a result, an excellent error ratio characteristic can be acquired. Further, in set partitioning in FIG. 10, a good result can be obtained if a group including a variable node with a low degree is mapped to bit Y, and a group including a variable node with a high degree is mapped to bit X.

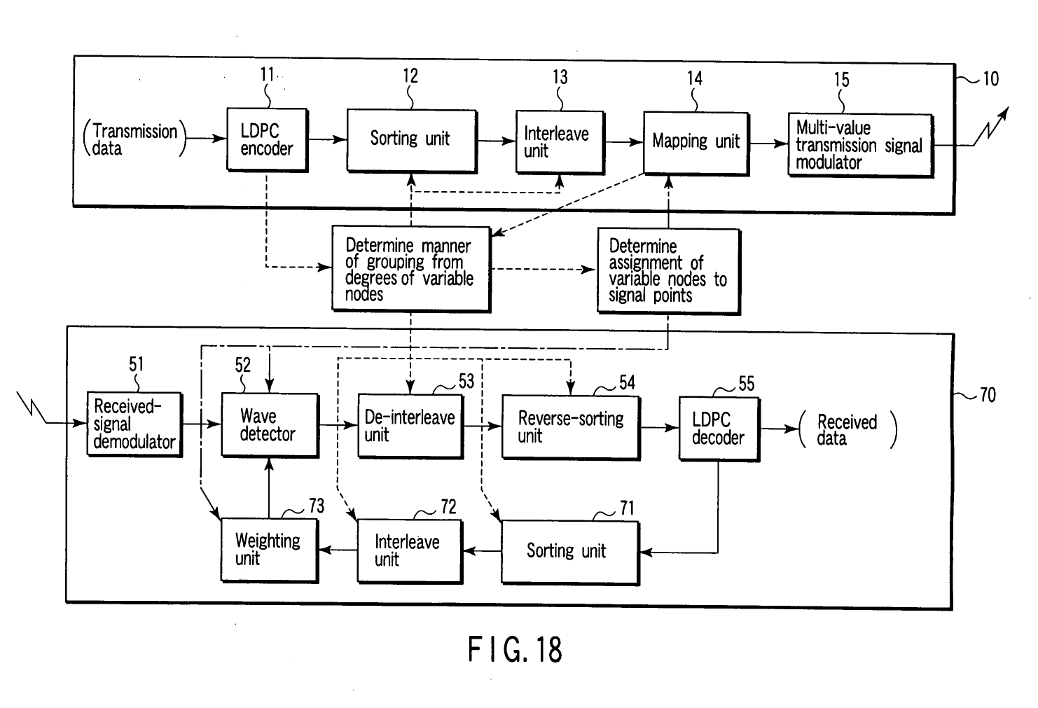

However, if the wave detector 52 can receive the determination result of the LDPC decoder 55 as in the radio receiving apparatus 70 shown in FIG. 18, described later, a good error ratio characteristic can be acquired in set partitioning when a group including a variable node with a high degree is assigned to bit Y, and a group including a variable node with a low degree is assigned to bit X. On the other hand, in gray labeling, a good error ratio characteristic can be acquired if the same assignment as in the radio receiving apparatus 50 is performed in the radio receiving apparatus 70 of FIG. 18.

As described above, by grouping based on the degrees of variable nodes, a coded bit sequence, i.e., a plurality of variable nodes, is assigned to each of binary labels of different error probabilities located at a plurality of modulation signal points. Accordingly, different error ratio characteristics are acquired even from the same signal point, depending upon the decoding process at the receiving side. Similarly, in any other modulation scheme, it is necessary to define how to assign, to the modulation signal points, the variable nodes grouped by labeling modulation signals, depending upon the arrangement of the signal points, labeling performed on the signal points and decoding method used. In the embodiment, grouping of variable nodes is made to correspond to labeling between a plurality of modulation schemes, and an optimal combination of the method of grouping and the assignment of coded bit sequences to signal points is detected depending upon the modulation scheme used.

### Second Embodiment

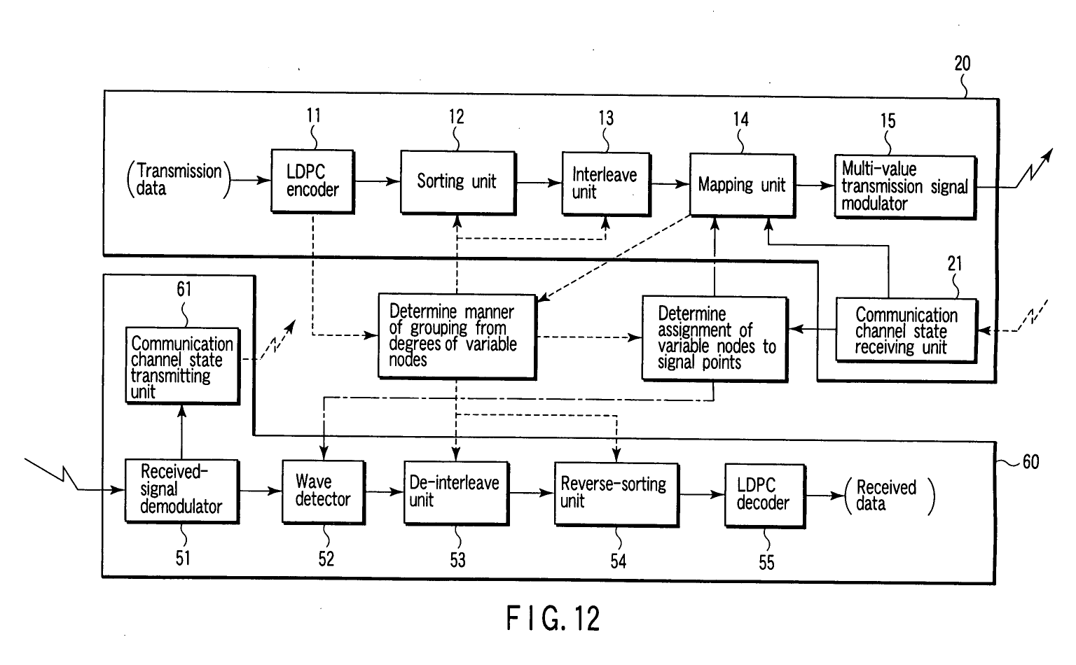

Referring to FIG. 12, a radio transmitting apparatus 20 and radio receiving apparatus 60 according to a second embodiment of the invention will be described. FIG. 12 is a block diagram illustrating configuration examples of the radio transmitting apparatus 20 and radio receiving apparatus 60.

The radio transmitting apparatus 20 of the second embodiment differs from the radio transmitting apparatus 10 of the first embodiment only in that the former additionally employs a communication channel state receiving unit 21. Further, the radio receiving apparatus 60 of the second embodiment differs from the radio receiving apparatus 50 of the first embodiment only in that the former additionally employs a communication channel state transmitting unit 61. In the first and second embodiments, like reference numerals denote like components, and duplication of explanation will be avoided.

The communication channel state receiving unit 21 receives, from the radio receiving apparatus 60, a signal including a communication channel state. The mapping unit 14 determines the mapping pattern of a plurality of coded bit sequences to be mapped to respective modulation signal points, in accordance with the received communication channel state.

The communication channel state transmitting unit 61 detects a communication channel state due to fading, based on the signal received by the received signal demodulator 51, and transmits a signal including the communication channel state, to the communication channel state receiving unit 21 of the radio transmitting apparatus 20. Further, the communication channel state transmitting unit 61 may determine the mapping pattern of a plurality of coded bit sequences to be mapped to respective modulation signal points, in accordance with the received communication channel state, and transmits it to the radio receiving apparatus 60. In this case, the communication channel state receiving unit 21 receives the mapping pattern from the radio receiving apparatus 60, and the mapping unit 14 performs mapping in accordance with the received mapping pattern.

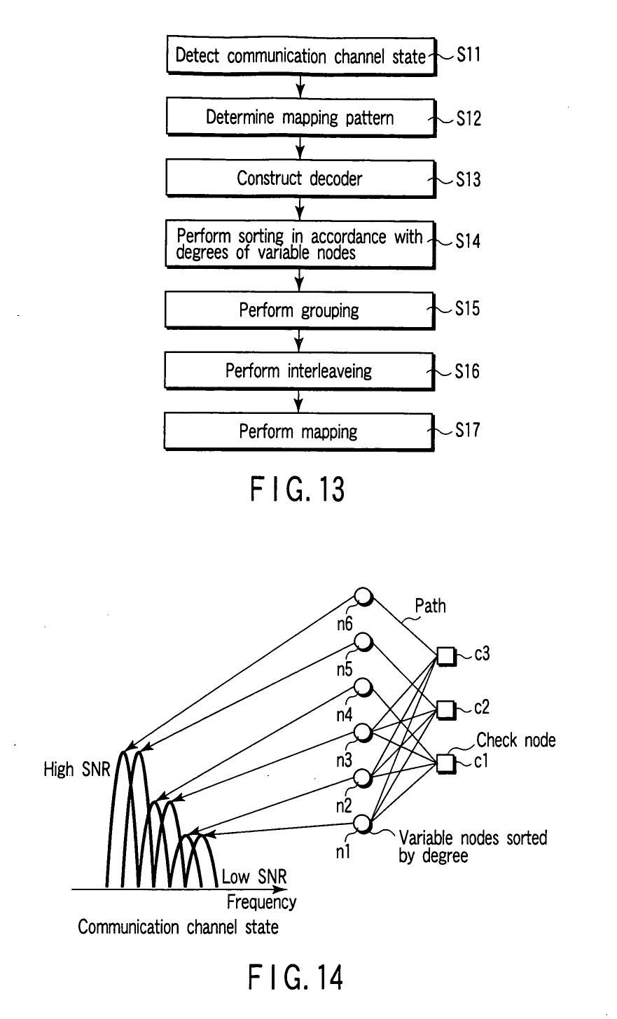

Referring now to FIG. 13, the operation of the radio transmitting apparatus 20 will be described. FIG. 13 is a flowchart useful in explaining the operation of the radio transmitting apparatus 20.

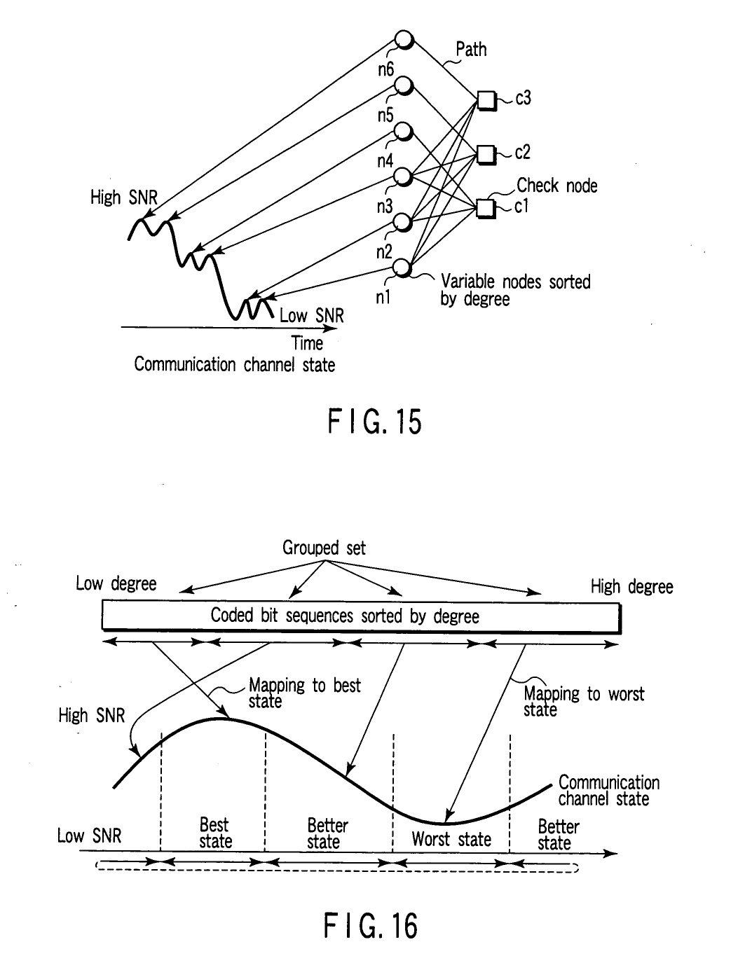

Firstly, the communication channel state receiving unit 21 receives, from the radio receiving apparatus 60, a signal including a communication channel state, and the radio transmitting apparatus 20 recognizes the frequency-base or time-base degraded state of the communication channel (step S11). The mapping unit 14 determines the mapping pattern of coded bit sequences in accordance with the detected communication channel state (step S12). A method for determining the mapping pattern will be described later with reference to FIG. 14 (concerning the frequency-base state) and FIG. 15 (concerning the time-base state).

In accordance with the mapping pattern determined at step S12, the structure of the decoder is determined, and the LDPC encoder 11 receives and encodes transmission data (step S13). The sorting unit 12 sorts each acquired coded bit sequence in accordance with the degrees of variable nodes acquired from the parity check matrix H (step S14). The sorting unit 12 then divides the sorted coded bit sequence into a predetermined number of groups corresponding to the modulation scheme employed in the radio transmitting apparatus 20 (step S15).

The interleave unit 13 interleaves the code bits in units of groups made by the sorting unit 12 (step S16). In accordance with the mapping pattern determined at step S12, the mapping unit 14 maps each coded bit in each group to the corresponding modulation signal point (step S17).

Referring to FIGS. 14 and 15, a method employed at step S12 for determining a mapping pattern will be described. FIG. 14 is a view useful in explaining the determination of a variable node, assigned to a certain subcarrier, in accordance with the frequency-base signal-to-noise ratio (SNR). FIG. 15 is a view useful in explaining the determination of a variable node, assigned to a certain subcarrier, in accordance with the time-base SNR.

In a multi-carrier communication system having the frequency characteristic shown in FIG. 14, SNR (i.e., the communication channel state) differs between subcarriers. In this case, a variable node with a high degree, i.e., having a high error resistance, is assigned to a subcarrier in a bad channel state, while a variable node with a low degree, i.e., having a low error resistance, is assigned to a subcarrier in a good channel state. This prevents degradation of the characteristics of the entire multi-carrier communication system.

Also in a communication channel system having a varying time-base characteristic as shown in FIG. 15, a group with a low error resistance, included in each coded bit sequence, is assigned to a time-base point of a high SNR, while a group with a high error resistance is assigned to a time-base point of a low SNR. This prevents degradation of the characteristics of the entire multi-carrier communication system.

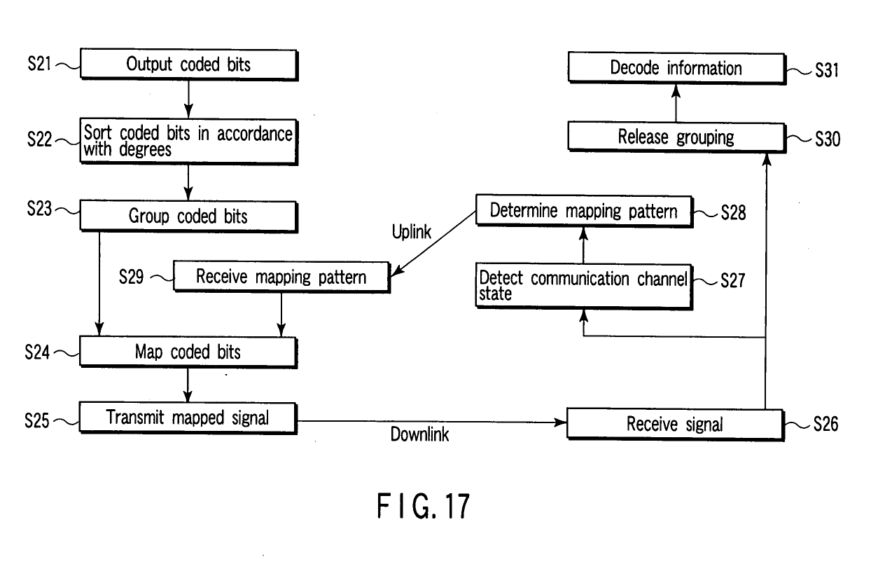

Further, the above-described mapping method can perform appropriate control in a communication channel state having a time-base or frequency-base cycle. This will be described referring to FIG. 16. FIG. 16 shows the control of mapping of each LDPC coded bit sequence in accordance with a communication channel state.

When the communication channel state varies as shown in FIG. 16, the communication channel state receiving unit 21 detects the time-base communication channel state in a target period of time. Subsequently, the unit 21 divides error characteristics into several groups of different levels within the target period. The sorting unit 12 divides each LDPC coded bit sequence into groups in accordance with the groups made by the communication channel state receiving unit 21, and maps the groups to respective error resistance levels. This enables the communication channel state varying with time to be promptly dealt with, without changing the structure of the encoder in accordance with the communication channel state, but simply using information concerning the mapping of the outputs of the encoder at both transmitter and receiver sides.

In a communication channel state having a time-base or frequency-base cycle, error control can be performed in accordance with the state of communication without changing the setting of the encoder and interleave unit, but simply by setting the start position of mapping of each coded bit sequence, sorted using the degrees of variable nodes, in accordance with the communication channel state.

Referring to FIG. 17, a further description will be given of the operation examples of the radio transmitting apparatus 20 and radio receiving apparatus 60 explained with reference to FIG. 16.

The LDPC encoder 11 outputs a coded bit sequence (step S21), and the sorting unit 12 sorts the coded bit sequence in accordance with the corresponding degrees (step S22), and divides the sorted coded bit sequence into groups in accordance with SNR (step S23). After that, the mapping unit 14 maps the groups to, for example, respective subcarriers in accordance with the states of the subcarriers (step S24). The multi-ary transmission signal modulator 15 modulates the mapped signal and transmits it to the radio receiving apparatus 60 (step S25).

In the radio receiving apparatus 60, the received signal demodulator 51 receives the signal from the radio transmitting apparatus 20 (step S26), the communication channel state transmitting unit 61 detects the communication channel state (step S27). After that, a mapping pattern indicating how to map the coded bits of the groups to the modulation signal points in accordance with the detected communication channel state is determined and transmitted to the radio transmitting apparatus 20 (step S28). Upon receiving the mapping pattern, the radio transmitting apparatus 20 performs mapping in accordance with the mapping pattern (step S29). Further, the signal transmitted from the radio transmitting apparatus 20 to the radio receiving apparatus 60 are released from the groups through the wave detector 52 to the reverse-sorting unit 54 (step S30), and are decoded by the LDPC decoder 55 (step S31).

In the radio transmitting apparatus 20 that operates as described above, it is not necessary to transmit all information concerning the communication channel state using an uplink in order to reconstruct the encoder in accordance with the communication channel. It is sufficient if the radio transmitting apparatus 20 only transmits information concerning a mapping pattern resulting from grouping. Therefore, it is possible to commonly use, at high speed, the mapping pattern of coded bit sequences suitable for the communication channel state at the downlink side. In this case, the number of grouping patterns is set to many groups if a more detailed communication channel state should be dealt with, and is set to a few groups if the degradation of characteristics can be suppressed within a certain range. This can minimize the amount of processing for mapping, and facilitate the encoding of bit data in accordance with the communication channel state.

The radio communication system using LDPC codes, according to the second embodiment employs means for detecting a change in time-base or frequency-base communication channel state due to, for example, fading. As a result, mapping of coded bit sequences can be controlled in accordance with the states of communication channels, which enables information to be decoded more accurately.

### Third Embodiment

Referring to FIG. 18, a radio transmitting apparatus 10 and radio receiving apparatus 70 according to a third embodiment of the invention will be described. FIG. 18 is a block diagram illustrating configuration examples of the radio transmitting apparatus 10 and radio receiving apparatus 70.

The radio transmitting apparatus 10 of the third embodiment is similar to the radio transmitting apparatus 10 of the first embodiment. On the other hand, the radio receiving apparatus 70 of the third embodiment differs from the radio receiving apparatus 50 of the first embodiment only in that the former additionally employs a sorting unit 71, interleave unit 72 and weighting unit 73. In the first and third embodiments, like reference numerals denote like components, and duplication of explanation will be avoided.

In the third embodiment, the radio receiving apparatus 70 repeatedly performs decoding of a received signal.

The sorting unit 71 and interleave unit 72 have the same structures as the sorting unit 12 and interleave unit 13, and perform operations opposite to the reverse-sorting unit 54 and de-interleave unit 53, respectively. More specifically, the sorting unit 71 sorts the likelihood-values of variable nodes, and the interleave unit 72 interleaves the sorted likelihood-values.

The weighting unit 73 calculates, from the likelihood-values of the variable nodes, a weight to be applied to the likelihood-value of a received signal in the wave detector 52, and outputs the weight to the wave detector 52. The wave detector 52 corrects the likelihood-value of the received signal in accordance with the weight.

Accordingly, in the third embodiment, the likelihood-value of a received signal can be calculated more accurately than in the first embodiment, and hence information can be more accurately decoded than in the first embodiment.

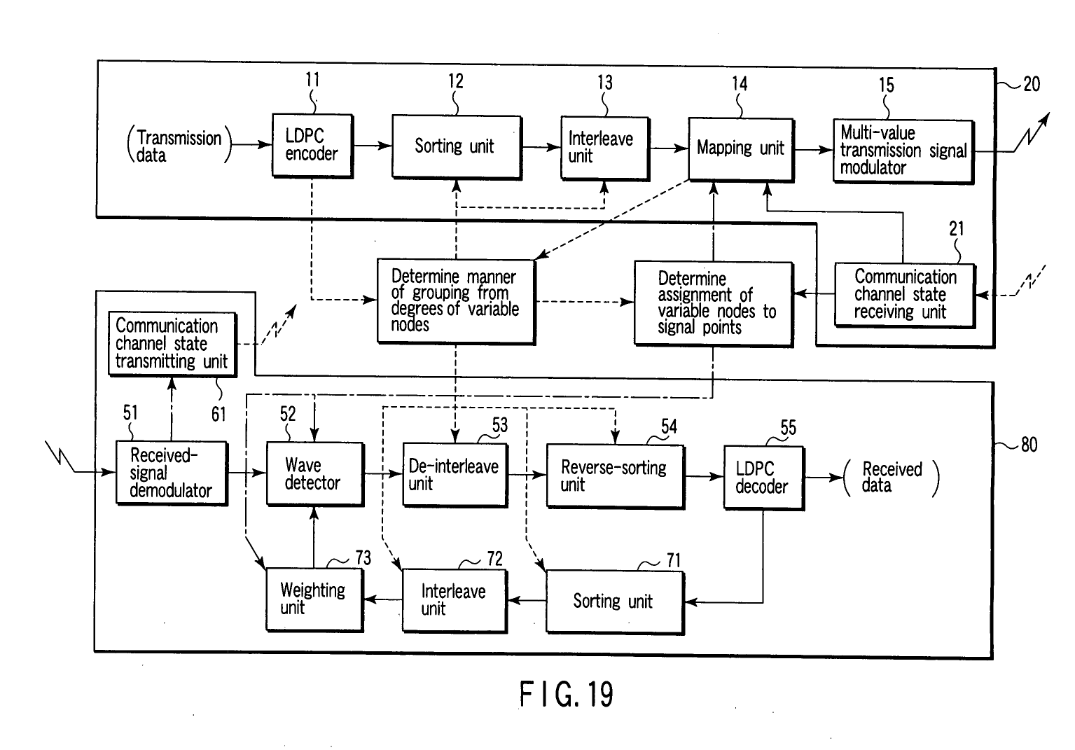

FIG. 19 shows a modification of the third embodiment. In this modification, the radio transmitting apparatus and radio receiving apparatus additionally employ a unit capable of detecting a communication channel state. In other words, this modification is acquired by combining the second and third embodiments, and accordingly, operates in the same manner as the radio communication system acquired by combining the second and third embodiments, and provides the same advantage as the latter.

As described above, the radio communication system using LDPC codes, according to the third embodiment, can more accurately decode information.

### Fourth Embodiment

A radio communication system according to a fourth embodiment performs not only grouping of each coded bit sequence using the degrees corresponding to the bits included in each coded bit sequence, but also grouping of a plurality of coded bit sequences using the degrees of the bits included in the plurality of coded bit sequences.

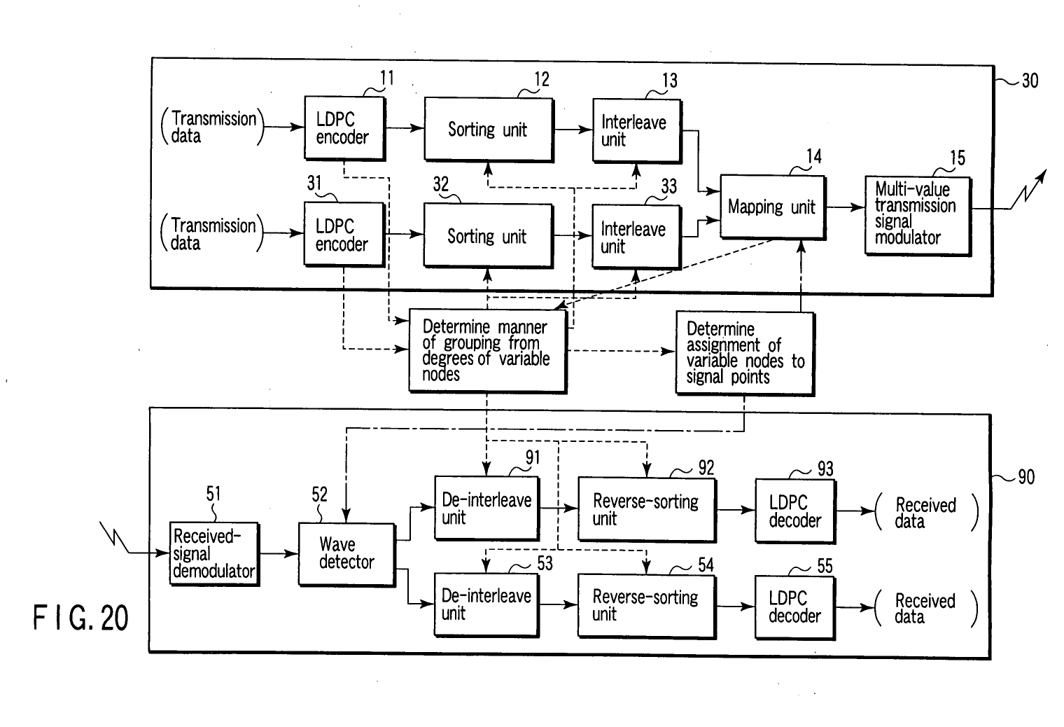

Referring to FIG. 20, a description will be given of a radio transmitting apparatus 30 and radio receiving apparatus 90 incorporated in the radio communication system of the fourth embodiment.

The radio transmitting apparatus 30 of the fourth embodiment differs from the radio transmitting apparatus 10 of the first embodiment only in that the former incorporates a plurality of LDPC encoders, sorting units and interleave units. Specifically, as seen from FIG. 20, the radio transmitting apparatus 30 is formed by adding, to the radio transmitting apparatus 10, another LDPC encoder 31, sorting unit 32 and interleave unit 33. In other words, the radio transmitting apparatus 30 includes two LDPC encoders, sorting units and interleave units. Further, the radio receiving apparatus 90 of the fourth embodiment differs from the radio receiving apparatus 50 of the first embodiment only in that the former includes a plurality of de-interleave units, reverse-sorting units and LDPC decoders. In the first and fourth embodiments, like reference numerals denote like components, and duplication of explanation will be avoided. In the radio transmitting apparatus 30, the same number of LDPC encoders, sorting units and interleave units as that of de-interleave units, reverse-sorting units and LDPC decoders are employed. In this embodiment, the number is set to two as described above.

In the radio communication system of the fourth embodiment, a plurality of transmission data items are encoded by the respective LDPC encoders. In the radio transmitting apparatus 30, transmission data is LDPC-encoded, sorted and grouped in units of transmission data items, and the mapping unit 14 maps, to respective modulation signal points, the groups of coded bit sequences acquired from all transmission data items.

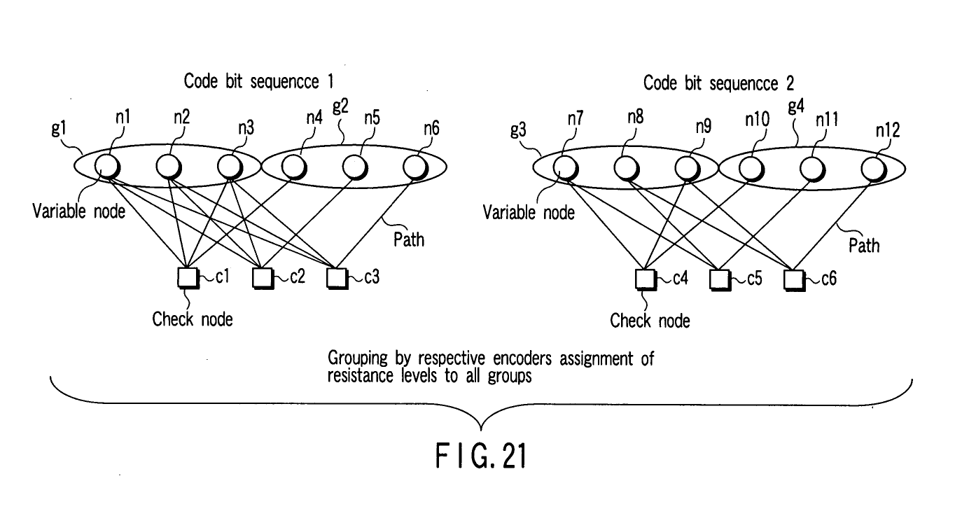

Specifically, as shown, for example, in FIG. 21, a coded bit sequence 1 and coded bit sequence 2 are acquired from two transmission data items through the LDPC encoder 11, sorting unit 12 and interleave unit 13. These coded bid sequences are grouped as indicated by ellipses that surround variable nodes. The coded bit sequence 1 is divided into two groups g1 and g2, while the coded bit sequence 2 is divided into two groups g3 and g4. After that, when the groups are mapped, all groups g1 to g4 of the coded bit sequences 1 and 2 are simultaneously mapped to the respective modulation signal points.

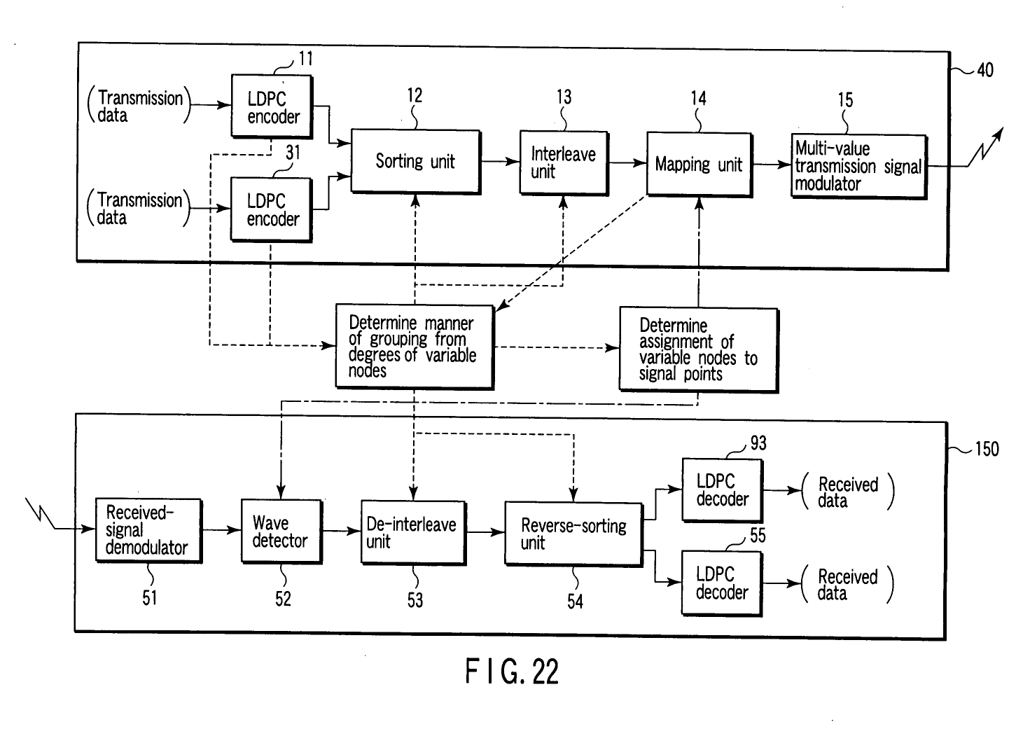

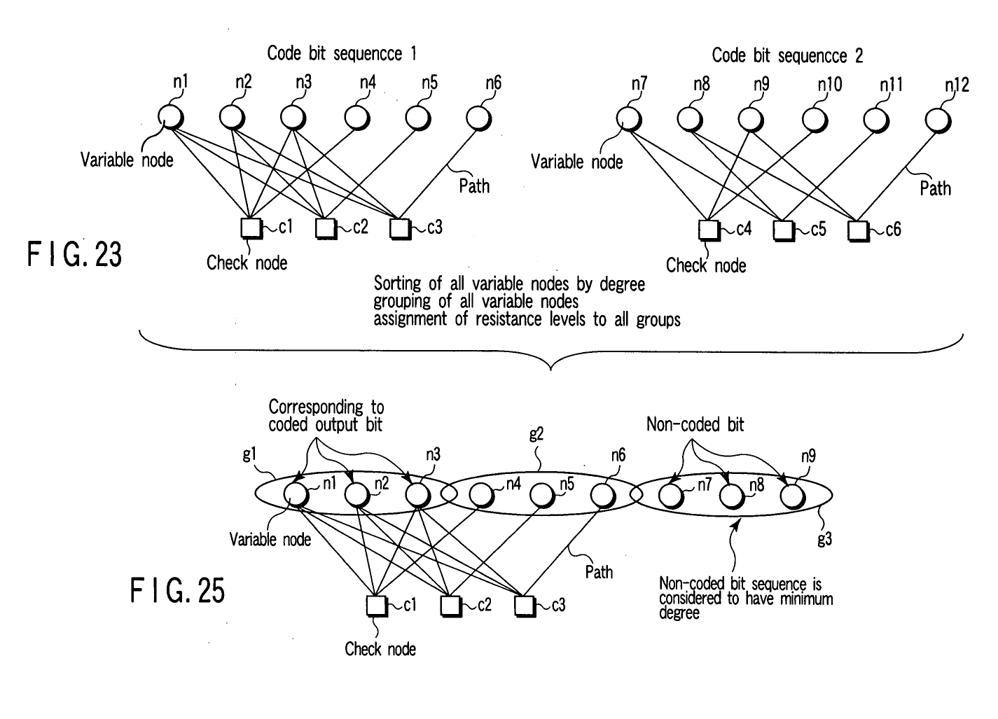

Referring to FIG. 22, a first modification of the fourth embodiment will be described. FIG. 22 is a block diagram illustrating a radio transmitting apparatus 40 and radio receiving apparatus 150 according to the first modification.

The radio transmitting apparatus 40 of the first modification differs from the radio transmitting apparatus 30 only in that the former includes a plurality of LDPC encoders and a single sorting unit and interleave unit. Further, the radio receiving apparatus 150 of the first modification differs from the radio receiving apparatus 90 only in that the former includes a plurality of LDPC decoders and a single reverse-sorting unit and de-interleave unit. In the first modification and fourth embodiment, like reference numerals denote like components, and duplication of explanation will be avoided. The radio transmitting apparatus 40 employs the same number of LDPC encoders as that of LDPC decoders employed in the radio receiving apparatus 150. In the modification, the number is set to two.

Also in the first modification, a plurality of transmission data items are encoded by the respective LDPC encoders. However, the first modification differs from the fourth embodiment in that in the former, the processes after sorting are not performed in units of transmission data items, but in units of two LDPC-encoded transmission data items.

In the radio transmitting apparatus 40, each transmission data items is LDPC-encoded, and two LDPC-encoded transmission data items are simultaneously input to the sorting unit 12. As a result, in units of two transmission data items, the LDPC-encoded transmission data is synthesized and sorted by the sorting unit 12 and interleaved by the interleave unit 13. On the other hand, the mapping unit 14 simultaneously maps, to respective modulation signal points, the groups of transmission bit sequences acquired from all transmission data.

Specifically, as shown, for instance, in FIG. 23, the LDPC encoders 11 and 31, to which two transmission data items are input, produce coded bit sequences 1 and 2, respectively. These two coded bit sequences are simultaneously input to the sorting unit 12. In this modification, grouping is executed on all variable nodes of the coded bit sequences 1 and 2, ranging from a variable node n1 to a variable node nl2. After that, when mapping is performed, all groups of transmission bit sequences acquired from the coded bit sequences 1 and 2 are mapped to the respective modulation signal points.

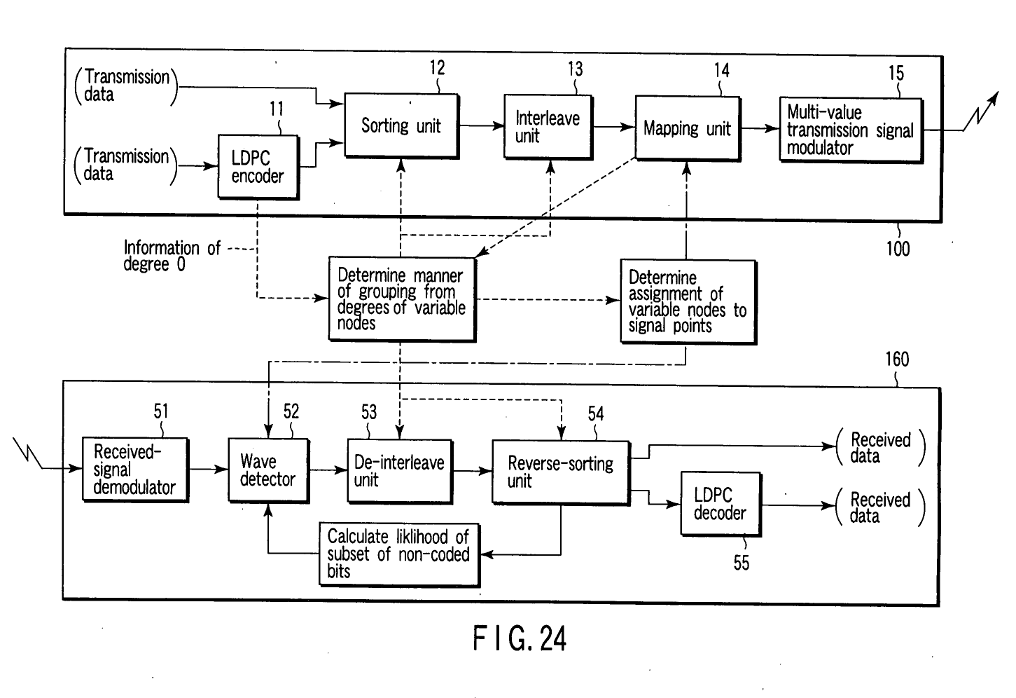

Referring then to FIG. 24, a second modification of the fourth embodiment will be described. FIG. 24 is a block diagram illustrating a radio transmitting apparatus 100 and radio receiving apparatus 160 according to the second modification.

The radio transmitting apparatus 100 of the second modification differs from the radio transmitting apparatus 40 of the first modification only in that the former employs no LDPC encoder 31. In the apparatus 100, some of input transmission data items are input to the LDPC encoder 11 and then to the sorting unit 12. On the other hand, some other input transmission data items are directly input to the sorting unit 12, without being encoded.

Further, the radio receiving apparatus 160 of the second modification differs from the radio receiving apparatus 150 of the first modification only in that the former employs no LDPC decoder 93. When the radio receiving apparatus 160 receives encoded data, the LDPC decoder 55 decodes the received data, whereas when it receives non-coded data, the LDPC decoder 55 is not used. After encoded data is decoded, non-encoded data is extracted from the wave detector 52 using information concerning the decoded data.

Specifically, as shown, for instance, in FIG. 25, certain transmission data is directly input as a non-coded bit sequence to the sorting unit 12, while other transmission data is first input to the LDPC encoders 11, and then input as a coded bit sequence to the sorting unit 12. The sorting unit 12 sorts both the non-coded bit sequence and coded bit sequence, and the interleave unit 13 interleaves the sorted bit sequences. When the sorting unit 12 groups the non-coded bit sequence and coded bit sequence by degree, the non-coded bit sequence is considered to have the minimum degree when it is sorted and grouped. After that, the mapping unit 14 maps each group of coded bit sequence to the corresponding modulation signal point.

As described above, the radio communication system of the fourth embodiment, in which not only a single coded bit sequence but also a plurality of coded bit sequences are LDPC-encoded, can more accurately decode information.

### Fifth Embodiment

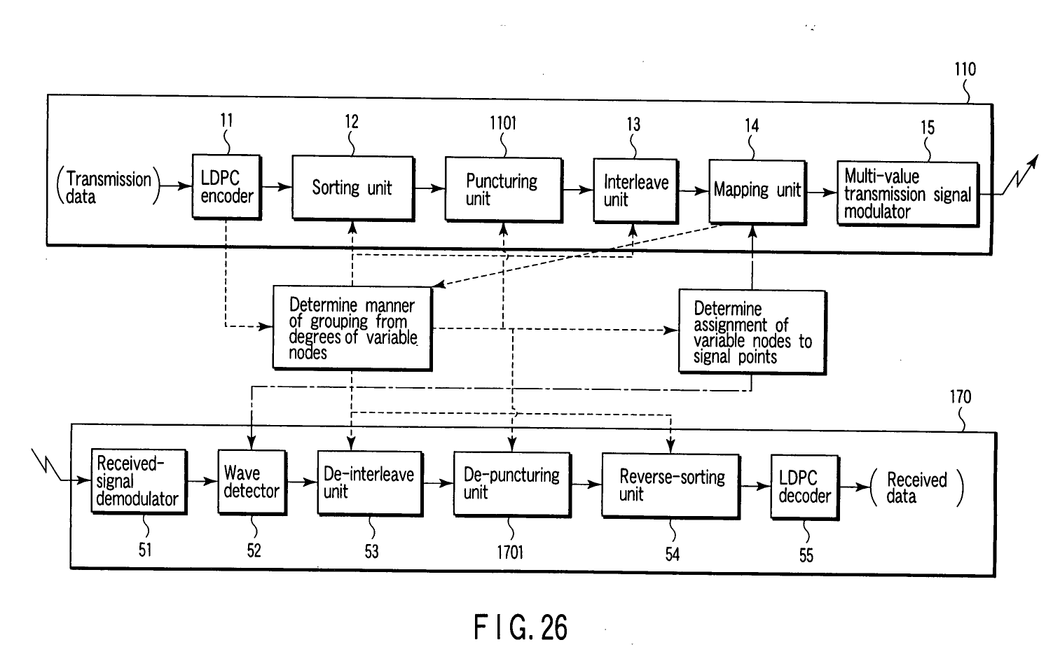

Referring to FIG. 26, a description will be given of a radio transmitting apparatus 110 and radio receiving apparatus 170 according to a fifth embodiment.

The radio transmitting apparatus 110 of the fifth embodiment differs from the radio transmitting apparatus 10 of the first embodiment only in that the former additionally incorporates a puncturing unit 1101. Further, the radio receiving apparatus 170 of the fifth embodiment differs from the radio receiving apparatus 50 of the first embodiment only in that the former additionally includes a de-puncturing unit 1701. In the first and fifth embodiments, like reference numerals denote like components, and duplication of explanation will be avoided.

The puncturing unit 1101 punctures the group of coded bit sequence grouped by the sorting unit 12, which has the highest error resistance, so that the radio transmitting apparatus 1101 does not transmit this group. It is very possible that the group of the highest error resistance is restored by error correction from a received signal corresponding to coded bit sequences that have not been punctured. Therefore, it is little possible that data communication is interrupted by the puncture of the group of the highest error resistance.

The de-puncturing unit 1701 is used to enable a likelihood-value corresponding to a punctured coded bit sequence to be used as a likelihood-value corresponding to a received signal.

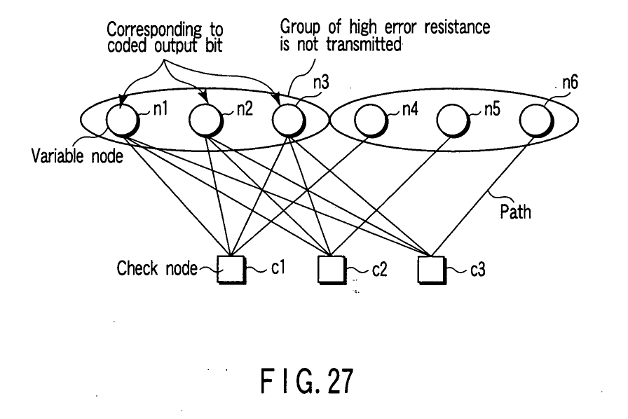

Referring to FIG. 27, an example of a coded bit sequence will be described. In FIG. 27, a coded bit sequence corresponding to variable nodes n1, n2 and n3 shown in FIG. 27 belongs to a group of the highest error resistance (with degree 3). Further, a coded bit sequence corresponding to variable nodes n4, n5 and n6 belongs to a group (with degree 1) to be transmitted. Even if the radio transmitting apparatus 110 does not transmit the group (with degree 3) of coded bit sequence of the highest error resistance, the radio receiving apparatus 170 can decode the coded bit sequence of the highest error resistance. This can be realized by mapping a received coded bit sequence group (with degree 1), and receiving information through a path connected to a variable node included in the group (with degree 3) of the highest error resistance. In this case, the amount of information actually transmitted can be reduced, which enhances the transmission rate.

In the fifth embodiment, if grouping is performed using information on the sequencing of error resistance levels acquired from the sorting of variable nodes by degree, a puncture pattern having a high error resistance can be easily detected by puncturing groups of a high error resistance.

In the above-described radio communication system using LDPC codes according to the fifth embodiment, since the amount of data transmitted by the radio transmitting apparatus 110 can be reduced by puncturing, the rate of data transmission can be enhanced with the transmission data accurately decoded.

The flow charts of the embodiments illustrate methods and systems according to the embodiments of the invention. It will be understood that each block of the flowchart illustrations, and combinations of blocks in the flowchart illustrations, can be implemented by computer program instructions. These computer program instructions may be loaded onto a computer or other programmable apparatus to produce a machine, such that the instructions which execute on the computer or other programmable apparatus create means for implementing the functions specified in the flowchart block or blocks. These computer program instructions may also be stored in a computer-readable memory that can direct a computer or other programmable apparatus to function in a particular manner, such that the instruction stored in the computer-readable memory produce an article of manufacture including instruction means which implement the function specified in the flowchart block of blocks. The computer program instructions may also be loaded onto a computer or other programmable apparatus to cause a series of operational steps to be performed on the computer or other programmable apparatus to produce a computer programmable apparatus provide steps for implementing the functions specified in the flowchart block or blocks.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method for mapping of coded bits using a low density parity check (LDPC) code, comprising:
encoding information bits by using the LDPC code to generate coded bits;
sorting the coded bits in accordance with degrees of variable nodes represented by a parity check matrix of the LDPC code;
dividing the sorted coded bits into a plurality of groups in accordance with a using modulation scheme; and
mapping the coded bits to respective modulation signal points by considering an error resistance of each of the groups and an error resistance of a corresponding one of the modulation signal points.

2. The method according to claim 1, further comprising interleaving the coded bits in units of groups.

3. The method according to claim 1, further comprising detecting a communication channel state between a transmitting apparatus and a receiving apparatus; and
mapping the coded bits to respective modulation signal points by considering an error resistance of each of the groups, an error resistance of a corresponding one of the modulation signal points and the detected communication channel state.

4. The method according to claim 3, further comprising interleaving the coded bits in units of groups.

5. A transmitting apparatus for transmitting coded data, comprising:
an encoder which encodes information bits using a low density parity check (LDPC) code, and generates coded bits;
a sorting unit configured to sort the coded bits in accordance with degrees of variable nodes represented by a parity check matrix of the LDPC code;
a dividing unit configured to divide the sorted coded bits into a plurality of groups in accordance with a using modulation scheme; and
a mapping unit configured to map the coded bits to respective modulation signal points by considering an error resistance of each of the groups and an error resistance of a corresponding one of the modulation signal points provides each of the sufficient error resistances;
a modulation unit configured to modulate the mapped coded bits using the modulation scheme; and
a transmitting unit configured to transmit the modulated mapped coded bits.

6. The apparatus according to claim 5, further comprising an interleaving unit configured to interleave the coded bits in units of groups.

7. A receiving apparatus comprising a receiving unit configured to receive the modulated mapped coded bits from the transmitting apparatus of claim 5.

8. A program stored in a computer readable medium, the program for mapping of coded bits using a low density parity check (LDPC) code, the program comprising:
means for instructing the computer to encode information bits using the LDPC code and generate coded bits;
means for instructing the computer to sort the coded bits in accordance with degrees of variable nodes represented by a parity check matrix of the LDPC code;
means for instructing the computer to divide the sorted coded bits into a plurality of groups in accordance with a using modulation scheme; and
means for instructing the computer to map the coded bits to respective modulation signal points by considering an error resistance of each of the groups and an error resistance of a corresponding one of the modulation signal points.

9. The program according to claim 8, further comprising means for instructing the computer to interleave the coded bits in units of groups.

10. A program stored in a computer readable medium, the program for mapping of coded bits using a low density parity check (LDPC) code, the program comprising:
means for instructing the computer to encode information bits using the LDPC code and generate coded bits;
means for instructing the computer to sort the coded bits in accordance with degrees of variable nodes represented by a parity check matrix of the LDPC code;
means for instructing the computer to divide the sorted coded bits into a plurality of groups in accordance with a using modulation scheme;
means for instructing the computer to detect a communication channel state between a transmitting apparatus and a receiving apparatus; and
means for instructing the computer to map the coded bits to respective modulation signal points by considering an error resistance of each of the groups, an error resistance of a corresponding modulation signal point of the modulation signal points and the detected communication channel state.

11. The program according to claim 10, further comprising means for instructing the computer to interleave the coded bits in units of groups.
